(19) United States
(12) Patent Application Publication
(10) Pub. No.: US 2011/0273081 A1
(43) Pub. Date: Nov. 10, 2011

(54) VISIBILITY ENHANCING FILM, METHOD OF FORMING THE SAME, ORGANIC LIGHT-EMITTING APPARATUS INCLUDING THE VISIBILITY ENHANCING FILM

(75) Inventors: Sung-Soo Koh, Yongin-city (KR); Soon-Ryong Park, Yongin-city (KR); Chul-Woo Jeong, Yongin-city (KR); Hee-Seong Jeong, Yongin-city (KR); Woo-Suk Jung, Yongin-city (KR); Il-Ryong Cho, Yongin-city (KR); Tae-Kyu Kim, Yongin-city (KR); Jae-Yong Kim, Yongin-city (KR)

(73) Assignee: Samsung Mobile Display Co., Ltd., Yongin-city (KR)

(21) Appl. No.: 13/077,297

(22) Filed: Mar. 31, 2011

(30) Foreign Application Priority Data
May 4, 2010 (KR) 10-2010-0042062

(51) Int. Cl. H01J 1/62; B32B 3/00

(52) U.S. Cl. 313/504; 428/156; 427/274

(57) ABSTRACT

A visibility enhancing film includes a polymer film; and photonic crystals disposed within a hole formed in the polymer film, with each of the photonic crystals comprising colloidal particles. A method of forming the visibility enhancing film and an organic light emitting apparatus including the visibility enhancing film are also provided.

### CLAIM OF PRIORITY

This application makes reference to, incorporates the same herein, and claims all benefits accruing under 35 U.S.C. §119 from an application earlier filed in the Korean Intellectual Property Office on the 4^{th} of May 2010 and there duly assigned Serial No. 10-2010-0042062.

### BACKGROUND OF THE INVENTION

1. Field of the Invention

Embodiments of the present invention relate to a visibility enhancing film, a method of forming the same, and an organic light emitting apparatus including the visibility enhancing film, and more specifically, to a visibility enhancing film having excellent reflectivity and transmittance, a method of forming the visibility enhancing film, and an organic light emitting apparatus including the visibility enhancing film.

2. Description of the Related Art

Organic light-emitting devices (OLEDs) are self-emitting devices. The OLEDs have advantages such as a wider viewing angle, more excellent contrast, quicker response, greater brightness, and more excellent driving voltage characteristics. The OLEDs may provide and display multicolored images.

### SUMMARY OF THE INVENTION

One aspect of the present invention provides a visibility enhancing film for preventing visibility deterioration introduced by external light.

Another aspect of the present invention provides a method of forming the visibility enhancing film.

Still another aspect of the present invention provides an organic light emitting apparatus including the visibility enhancing film.

In accordance with an embodiment of the present invention, a visibility enhancing film includes a polymer film; and photonic crystals formed to fill a recess formed on the polymer film, with each of the photonic crystals including colloidal particles.

The photonic crystals may have a pyramid shape, a cone shape, or a rod shape.

The colloidal particles may have a globular shape, an egg shape, or a peanut shape.

The colloidal particles may be selected from the group consisting of a polymer, a metal hydroxide, a metal oxide, a quantum dot, and a combination of at least two thereof.

The colloidal particles may be a polymer, wherein the polymer is selected from the group consisting of a polyester-based polymer, a polystyrene-based polymer, a polyacrylate-based polymer, a polymethacrylate-based polymer, a polycarbonate-based polymer, a polyether-based polymer, a polyalkyleneoxide-based polymer, a polyamide-based polymer, a polysiloxane-based polymer, and a combination of at least two thereof.

The colloidal particles may be a metal hydroxide, wherein the metal hydroxide is selected from the group consisting of an iron hydroxide, an aluminum hydroxide, a zinc hydroxide, a titanium hydroxide, a cerium hydroxide, a tin hydroxide, a thallium hydroxide, a barium hydroxide, a yttrium hydroxide, a zirconium hydroxide, a copper hydroxide, and a combination of at least two thereof.

The colloidal particles may be a metal oxide, wherein the metal oxide is selected from the group consisting of an iron oxide, an aluminum oxide, a zinc oxide, a titanium oxide, a cerium oxide, a tin oxide, a thallium oxide, a barium oxide, a yttrium oxide, a zirconium oxide, a copper oxide, and a combination of at least two thereof.

The colloidal particles may be a quantum dot, wherein the quantum dot is selected from the group consisting of magnesium (Mg), cadmium (Cd), titanium (Ti), lithium (Li), copper (Cu), aluminum (Al), nickel (Ni), yttrium (Y), silver (Ag), manganese (Mn), vanadium (V), iron (Fe), lanthanum (La), tantalum (Ta), niobium (Nb), gallium (Ga), indium (In), sulfur (S), selenium (Se), phosphorus (P), arsenic (As), cobalt (Co), chromium (Cr), boron (B), nitrogen (N), antimony (Sb), and a combination of at least two thereof.

The colloidal particles may be selected from the group consisting of starch, Arabic gum, clay, fat, and a combination of at least two thereof.

The colloidal particles included in the photonic crystal may have a simple cubic lattice structure, a simple hexagonal lattice structure, a body centered cubic lattice structure, a face centered cubic lattice structure, a hexagonal close packed lattice structure, or a diamond lattice structure.

The polymer film may be selected from the group consisting of a polyethyleneterephthalate-based resin, a polycarbonate-based resin, a polyethylenephthalate-based resin, a polyimide-based resin, a polyamide-based resin, a polyether-based resin, a polysulfone-based resin, a polypropylene-based resin, a polymethylmethacrylate-based resin, a acetylcellulose-based resin, a copolymer comprising at least two thereof, and a derivative thereof.

In accordance with another embodiment, a method of forming a visibility enhancing film includes steps of preparing a substrate; on the substrate, forming a polymer film forming material layer by providing a mixture including a polymer film forming material and a solvent; on the polymer film forming material layer, forming holes receiving a plurality of photonic crystals by contacting the polymer film forming material layer with a stamp having a predetermined pattern; providing a mixture including a colloidal particle and a dispersion medium inside each of the holes; and thermal-treating the resultant thereof.

The holes may have a pyramid shape, a cone shape, or a rod shape.

The dispersion medium may be selected from the group consisting of water, methanol, ethanol, ethyleneglycol, glycerol, perfluorodecalin, perfluoromethyldecalin, perfluorononane, perfluorocyclohexane, perfluoro-1,2-dimethylcyclohexane, perfluoro-2-methyl-2-pentene, perfluorokerosene, and a combination of at least two thereof.

In accordance with still another embodiment, an organic light-emitting apparatus includes an organic light emitting device; and the visibility enhancing film disposed in a path of light emitted from the organic light emitting device.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein;

FIG. 1A is a partial cross-sectional view schematically illustrating a visibility enhancing film constructed with an embodiment of the present invention;

FIG. 1B is a partial plan view schematically illustrating a visibility enhancing film constructed with an embodiment of the present invention;

FIGS. 2A through 2F are diagrams each illustrating a part of a lattice structure formed by colloidal particles included in a photonic crystal;

FIGS. 3A through 3C are diagrams for sequentially explaining a method of forming the visibility enhancing film of FIG. 1, in accordance with another embodiment of the present invention;

FIGS. 4A and 4B are photographic images of colloidal particles used respectively in Examples 1 and 2; and

FIGS. 5A and 5B are photographic images of colloidal particles stacked in photonic crystals respectively formed according to Examples 1 and 2.

### DETAILED DESCRIPTION OF THE INVENTION

A typical OLED has a structure including a substrate, and an anode, a hole transport layer (HTL), an emission layer (EML), an electron transport layer (ETL), and a cathode which are sequentially stacked on the substrate. In this regard, the HTL, the EML, and the ETL are organic thin films formed of organic compounds.

The principle of operation of an OLED having the above-described structure will be discussed as follows.

When a voltage is applied between the anode and the cathode, holes escaping from the anode move to the EML via the HTL, and electrons escaping from the cathode move to the EML via the ETL. The holes and electrons recombine in the EML to generate excitons. When the excitons drop from an excited state to a ground state, light is emitted.

Therefore, at least a part of the light generated in the OLED may be subjected to interference by an external source of light when the light emitted by the OLED is emitted to an external environment, and thus luminance and a contrast ratio of the OLED may deteriorate.

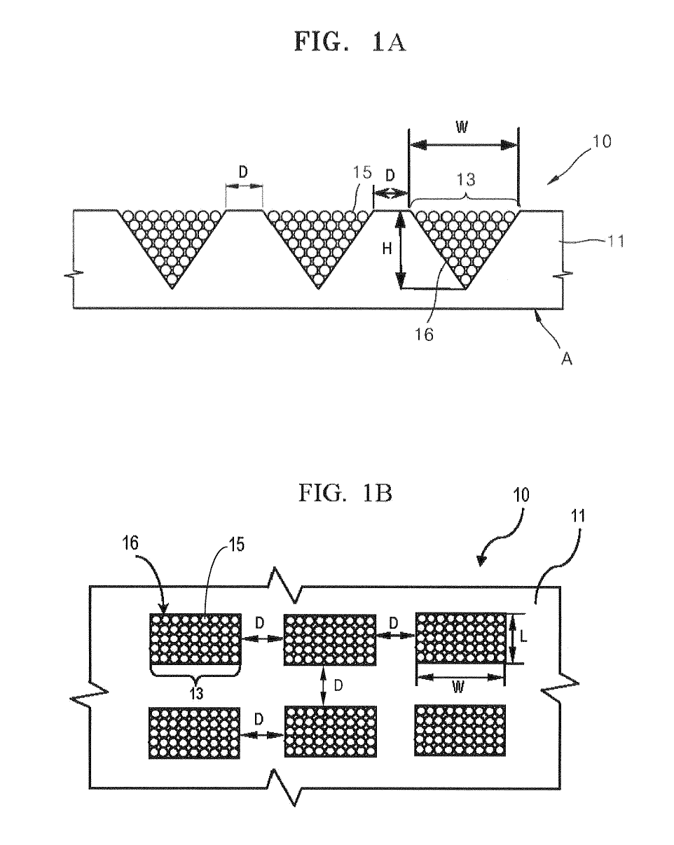

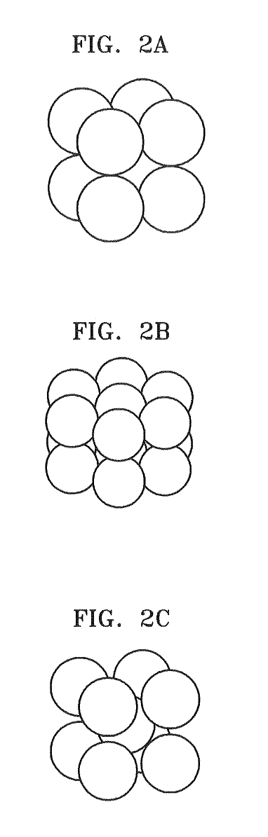

FIG. 1A is a partial cross-sectional view schematically illustrating a visibility enhancing film 10 constructed with an embodiment of the present invention. The visibility enhancing film 10 includes a polymer film 11 and photonic crystals 13. A photonic crystal 13 is formed inside each hole or recess 16 formed in the polymer film 11. The photonic crystal 13 includes colloidal particles 15.

The photonic crystal 13 may have a pyramid shape, a cone shape, or a rod shape, but the shape of photonic crystal is not limited thereto. As shown in FIG. 1B which illustrates a partial plan view of the visibility enhancing film 10, for example, the photonic crystal 13 may have an inverted or upside down quadrangular pyramid shape. When the photonic crystal 13 has an upside down quadrangular pyramid shape, an aspect ratio of a quadrangle constituting the base of the photonic crystal 13 may be variously adjusted. For example, the ratio of width W to length L of the quadrangle may be adjusted to be approximately 2:1, but is not limited to that ratio. In one embodiment, the photonic crystal 13 may be substantially transparent to visible light.

A distance D between two adjacent photonic crystals 13 may be selected within a range that does not deteriorate visibility. Also, the distances between the two adjacent photonic crystals 13 may be identical.

A minimum value of the distance D measured between the two adjacent photonic crystals 13 may be about 10 nm to about 10,000 nm, for example, from about 100 nm to about 500 nm. When the minimum value of the distance D is within the above range, the photonic crystals 13 may be not observed in an external environment, and thus visibility does not deteriorate due to the use of photonic crystals 13.

A size of the photonic crystal 13, for example a height H of the photonic crystal 13, a width W of the photonic crystal 13 (in the photonic crystal having a pyramid shape and a cone shape, for example, a length of the base side of a triangle constituting a cross-section of the photonic crystal 13 of FIG. 1A), or the like, may be selected while considering a photonic bandgap range to be realized, a type of colloidal particles used, and a thickness of a visibility enhancing film. When the photonic crystal 13 has a cone shape, the width W of the photonic crystal 13 of FIG. 1 may refer to the diameter of the base of the cone. For example, the height H of the photonic crystal 13 may be from about 50 nm to about 200 nm, for example, from about 90 nm to about 160 nm, and the width W of the photonic crystal 13 (for example, when the photonic crystal 13 has a quadrangle pyramid shape, a width or a length of a quadrangle constituting the base side) may be from about 200 nm to about 700 nm, for example, from about 240 nm to about 500 nm, but the height and width of the photonic crystal 13 are not limited thereto. Heights of a cone shaped-photonic crystal and a rod shaped-photonic crystal may be selected from above range of the height H of the photonic crystal 13 and diameters of the cross sections of the cone shaped-photonic crystal and the rod shaped-photonic crystal may be selected from above range of the width W of the photonic crystal 13.

For example, when the photonic crystal 13 has the quadrangle pyramid shape, a ratio of width W to length L of the quadrangle constituting the base side may be 2:1 or 1:2, and the value of the width W may be in a range from about 100 nm to about 150 nm.

The photonic crystal 13 is formed to fill the hole 16 formed on the polymer film 11, and includes the plurality of colloidal particles 15.

“Colloid” is a term indicating a dispersed state of a material, and generally, refers to particles larger than molecules or ions that are dispersed in a gas, liquid, or solid without agglomeration or precipitation. A “colloidal particle” is a term indicating a particle dispersed in a gas, liquid, or solid in a “colloid” state.

The colloidal particle 15 may have a globular shape, an egg shape, or a peanut shape, but is not limited thereto.

An average particle size of the colloidal particle 15 may be selected from a range for maintaining the colloid state. For example, when the colloidal particle 15 has a globular shape, the average particle size of the colloidal particle 15 may be from about 0.1 nm to about 1000 nm, for example from about 1 nm to about 300 nm, but is not limited thereto. Also, when the colloidal particle 15 has an egg shape or a peanut shape, the length of the longer axis of the colloidal particle 15 may be from about 0.1 nm to about 1000 nm, for example from about 1 nm to about 300 nm, but is not limited thereto.

The colloidal particle 15 may be either a polymer, a metal hydroxide, a metal oxide, a quantum dot, or a combination of at least two thereof.

When the colloidal particle 15 is a polymer, the polymer may be, but is not limited to, either a polyester-based polymer, a polystyrene-based polymer, a polyacrylate-based polymer, a polymethacrylate-based polymer, a polycarbonate-based polymer, a polyether-based polymer, a polyalkyleneoxide-based polymer, a polyamide-based polymer, a polysiloxane-based polymer, or a combination of at least two thereof. In detail, the polymer may be selected from either polystyrene, polymethylstyrene, polyacrylate, polymethylmethacrylate, polybenzylmethacrylate, polyphenylmethacrylate, poly-1-methylcyclohexylmethacrylate, polycyclohexylmethacrylate, polychlorobenzylmethacrylate, poly-1-phenylethylmethacrylate, poly-1,2-diphenylethylmethacrylate, polydiphenylmethylmethacrylate, polyfurfurylmethacrylate, poly-1-phenylcyclohexylmethacrylate, polypentachlorophenylmethacrylate, polypentabromophenylmethacrylate, polypropyleneoxide, polyethyleneoxide, polydimethylsiloxane, poly-N-isopropylacrylamide, or a copolymer of at least two of the monomers forming of the monomers.

When the colloidal particle 15 is a metal hydroxide, the metal hydroxide may be, but is not limited to, either an iron hydroxide, an aluminum hydroxide, a zinc hydroxide, a titanium hydroxide, a cerium hydroxide, a tin hydroxide, a thallium hydroxide, a barium hydroxide, a yttrium hydroxide, a zirconium hydroxide, a copper hydroxide, or a combination of at least two thereof.

When the colloidal particle 15 is a metal oxide, the metal oxide may be, but is not limited to, either an iron oxide (for example, F₂O₃), an aluminum oxide, a zinc oxide, a titanium oxide, a cerium oxide, a tin oxide, a thallium oxide, a barium oxide, a yttrium oxide, a zirconium oxide, a copper oxide, or a combination of at least two thereof.

When the colloidal particle 15 is a quantum dot, the quantum dot may be, but is not limited to, either magnesium (Mg), cadmium (Cd), titanium (Ti), lithium (Li), copper (Cu), aluminum (Al), nickel (Ni), yttrium (Y), silver (Ag), manganese (Mn), vanadium (V), iron (Fe), lanthanum (La), tantalum (Ta), niobium (Nb), gallium (Ga), indium (In), sulfur (S), selenium (Se), phosphorus (P), arsenic (As), cobalt (Co), chromium (Cr), boron (B), nitrogen (N), antimony (Sb), or a combination of at least two thereof. In detail, the quantum dot may be CdS, CdSe, GaAs, GaN, AlN, or InN, but is not limited thereto.

Alternatively, the colloidal particle 15 may be either starch, Arabic gum, clay, fat, or a combination of at least two thereof.

The starch may be a mixture of amylase and amylopectin. The Arabic gum is rubber obtained by drying liquid secreted from an acacia tree, and may include galactopyranose as a main component. The clay may be, for example, alumina silicate including sodium, calcium, potassium, or the like. The fat may be a molecule wherein glycerol and fatty acid form an ester bond.

The colloidal particle may be synthesized or obtained by using any well known method.

For example, to obtain a polystyrene colloidal particle, a mixture including deionized water, an emulsifier, a surfactant (for example, sodium styrene sulfonate), and a counteragent (for example, sodium hydrogen carbonate) is heated, for example, at 80° C. for 10 minutes, and then is stirred. Next, a styrene monomer is put into the mixture, and then an initiator, such as potassium persulfate, is put into the mixture. Then, the resulting product is polymerized under a nitrogen atmosphere to obtain the polystyrene colloidal particle.

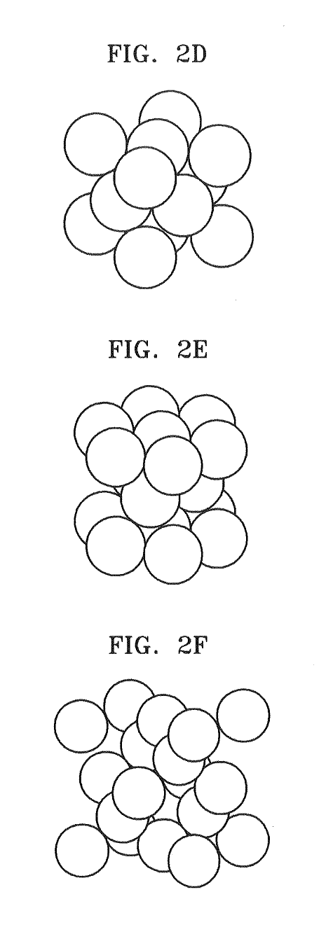

The plurality of colloidal particles 15 included in the photonic crystal 13 may have a lattice structure. For example, the colloidal particles 15 may have a simple cubic lattice structure (refer to FIG. 2A), a simple hexagonal lattice structure (refer to FIG. 2B), a body centered cubic lattice structure (refer to FIG. 2C), a face centered cubic (FCC) lattice structure (refer to FIG. 2D), a hexagonal close packed lattice structure (refer to FIG. 2E), or a diamond lattice structure (refer to FIG. 2F).

Air, a dispersion medium, or the like may exist between the colloidal particles 15 of the photonic crystal 13. Also, the colloidal particles 15 may include two materials having different refractive indexes. Accordingly, at least two materials having different refractive indexes may be regularly arranged 2-dimensionally or a 3-dimensionally in the photonic crystal 13. The materials may have a lattice structure as described in FIGS. 2A through 2F. A certain wavelength band, which an incident light cannot pass through in any direction, exists in the photonic crystal 13 due to a periodical refractive index distribution, and this certain wavelength band is referred to as a photonic bandgap.

For example, when the photonic bandgap of the photonic crystal 13 may be formed in an ultraviolet (UV) region and a frequency of light incident on the photonic crystal 13 corresponds to the photonic bandgap, theoretically at least 99% of the incident light may be reflected at the photonic crystal 13. On the other hand, a light having a frequency different from the photonic bandgap may pass through the photonic crystal 13. By using such a principle, the visibility enhancing film 10 including the photonic crystal 13 may be formed at a point where an organic light emitting device and an external environment contact each other while, for example, a surface A of FIG. 1A faces toward the organic light emitting device, thereby blocking an external light and effectively penetrating light generated in the organic light emitting device. Accordingly, the visibility enhancing film 10 may effectively improve luminance, a contrast ratio, or the like of an organic light emitting apparatus.

As described above, the photonic bandgap of the photonic crystal 13 may be formed in the UV region, but is not limited thereto.

The polymer film 11 may perform as a supporter for the photonic crystal 13 described above to be formed. The polymer film 11 is processable, and may be formed of a material that does not react with the colloidal particle 15 of the photonic crystal 13 and has excellent light transmittance.

For example, the polymer film 11 may be, but not limited to, either a polyethylene terephthalate-based resin (such as polyethyleneterephthalate (PET)), a polycarbonate-based resin, a polyethylenephthalate-based resin, a polyimide-based resin, a polyamide-based resin, a polyether-based resin, a polysulfone-based resin, a polypropylene-based resin, a polymethylmethacrylate-based resin, an acetylcellulose-based resin, a copolymer including at least two thereof, or a derivative thereof.

The polymer film 11 includes the plurality of holes 16. The photonic crystals 13 are formed in each hole 16.

A thickness of the visibility enhancing film 10 may be based on a shape of the photonic crystal 13, a type of the colloidal particles 15 used, or a type of the polymer film 11 used, and may be selected from a range of about 150 μm to about 250 μm.

A method of forming the visibility enhancing film 10 may include, for example preparing a substrate; forming a polymer film forming material layer by providing a mixture including the polymer film forming material and a solvent on the substrate; forming holes corresponding to a plurality of crystals on the polymer film forming material layer by contacting the polymer film forming material layer with a stamp having a predetermined pattern; and providing a mixture including a colloidal particle and a dispersion medium in the holes and then heat-treating the resultant thereof.

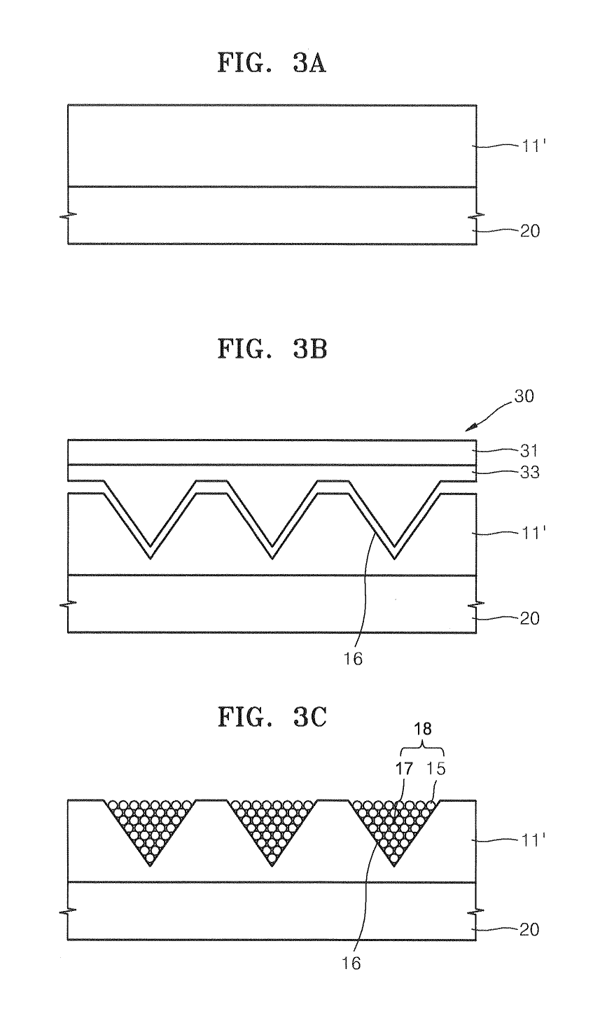

FIGS. 3A through 3C are diagrams for sequentially explaining the method of forming the visibility enhancing film 10 of FIG. 1A, according to an embodiment of the present invention.

Referring to FIG. 3A, a substrate 20 is prepared, and then a polymer film forming material layer 11′ is formed by providing a mixture including a polymer film forming material and a solvent on the substrate 20. The substrate 20 operates as a temporary supporter for forming the visibility enhancing film 10, and may be formed of a material that does not react with the polymer film forming material and is easily separated from the completed visibility enhancing film 10. The substrate 20 may be a glass substrate, but is not limited thereto. The visibility enhancing film 10 may be finally separated from the substrate 20.

The polymer film forming material may be a resin that may be included in the polymer film 11 of FIG. 1A, for example, a polycarbonate-based resin, a polyethylenephthalate-based resin, a polyimide-based resin, a polyamide-based resin, a polyether-based resin, a polysulfone-based resin, a polypropylene-based resin, a polymethyl methacrylate-based resin, an acetylcellulose-based resin, a copolymer including at least two thereof, or a derivative thereof, or a precursor thereof, for example a monomer or oligomer.

The solvent may be selected from among general solvents that are miscible with the polymer film forming material and are easily removed through heat-treatment, or the like.

The mixture including the polymer film forming material and the solvent is provided on the substrate 20, and then the polymer film forming material layer 11′ may be formed by leaving the substrate 20 at room temperature or soft-baking the substrate 20. The polymer film forming material layer 11′ may have viscoelasticity and ductility to form the hole 16 by using a stamp 30 that will be described later with reference to FIG. 2B. A condition of soft-baking the substrate 20 differs based on the polymer film forming material and the solvent, and the soft-baking may be performed at a temperature of about 50° C. to about 150° C. for about 1 minute to about 1 hour.

Then, as shown in FIG. 2B, the polymer film forming material layer 11′ and the stamp 30 having the predetermined pattern contact each other. Thus, the holes 16 corresponding to the plurality of photonic crystals 13 may be formed on the polymer film forming material layer 11′.

The stamp 30 may have a pattern 33 corresponding to a pattern of the hole 16. The stamp 30 may be prepared by using a master 31 formed of various materials, such as silicon, a polymer, a metal, quartz, etc. For example, the pattern 33 may be copied by pasting a polymer on the master 31, the pattern 33 may be copied in a metal form through plating, or the pattern 33 may be transferred onto a quartz, glass, or silicon wafer by using the master 31 and the polymer, and then the pattern 33 may be etched. The stamp 30 however may be prepared by using any other method.

Then, a mixture 18 including the colloidal particle 15 and a dispersion medium 17 is provided to the hole 16 formed on the polymer film forming material layer 11′ as shown in FIG. 3C.

The mixture 18 including the colloidal particle 15 and the dispersion medium 17 may be provided by using any well known method. Examples of such a well known method include a spin coating method, a spraying method, an inkjet printing method, a dipping method, a casting method, a gravure coating method, a bar coating method, a roll coating method, a wire bar coating method, a screen coating method, a flexography coating method, and an offset coating method, but are not limited thereto.

While providing the mixture 18, the colloidal particles 15 may closely adhere to each other to form a lattice structure, i.e., may self-assemble, according to evaporation of the dispersion medium 17 and a capillary force.

Then, the resulting product is heat-treated to remove at least a part of the solvent in the polymer film forming material layer 11′ (here, if the polymer film forming material is a monomer or oligomer, a reaction such as a crosslink may simultaneously occur), and to remove at least a part of the dispersion medium 17, thereby fixing the colloidal particles 15. Accordingly, the visibility enhancing film 10 shown in FIG. 1A may be formed. Here, a condition of heat-treatment differs based on the polymer film forming material, the colloidal particle 15, and a type of the dispersion medium 17. For example, the heat-treatment may be performed at a temperature from about 50° C. to about 150° C. for a period of time within a range extending from about 1 minute to 1 hour.

The visibility enhancing film 10 may be used in various electronic apparatus, such as a liquid crystal display apparatus or an organic light emitting apparatus.

For example, the visibility enhancing film 10 may be included in an organic light emitting apparatus including an organic light emitting device. Also, the surface A of the visibility enhancing film 10 of FIG. 1A may face toward the organic light emitting device.

The organic light emitting device includes an anode, a cathode, and an organic layer disposed between the anode and the cathode, wherein a light is generated as holes supplied from the anode and electrons supplied from the cathode recombine in the organic layer to generate excitons, and then as the excitons change into a ground state. The visibility enhancing film 10 may perform as a surface of the organic light emitting device contacting an external environment, such as the atmosphere, and is disposed on a path of light emitted from the organic light emitting device, thereby blocking an external light. Accordingly, luminance and a contrast ratio of the organic light emitting device may be increased. Thus, an organic light emitting apparatus having high quality may be realized. An adhesive layer for fixing the visibility enhancing film 10 to the organic light emitting device may be disposed between the organic light emitting device and the visibility enhancing film 10. For example, the adhesive layer may be disposed between the surface A of the visibility enhancing film 10 and the organic light emitting device to adhere the visibility enhancing film 10 to the organic light emitting device. Alternatively, a protective layer may be disposed on a surface of the visibility enhancing film 10 facing an external environment.

The present invention will be described in further detail with reference to the following examples. These examples are for illustrative purposes only and are not intended to limit the scope of the present invention.

### EXAMPLES

### Example 1

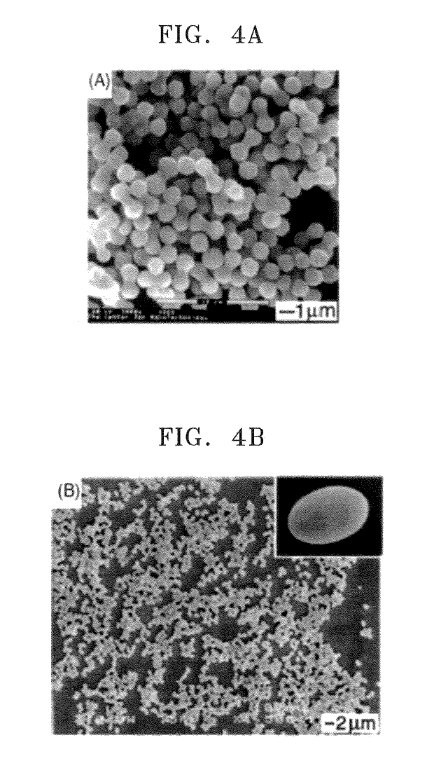

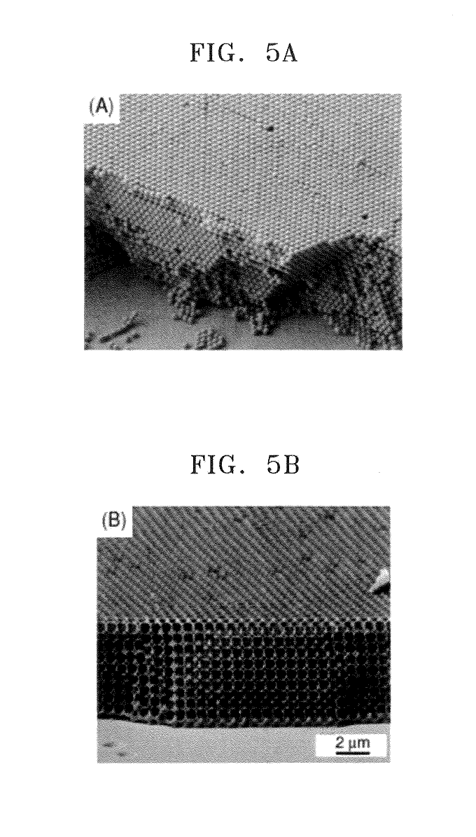

A mixture including a polyethyleneterephthalate resin was coated on a glass substrate, the glass substrate was soft-baked at 80° C. for 10 minutes to form a polyethyleneterephthalate (PET) resin layer, and then a copper stamp having a pattern of a plurality of pyramid shaped dents was pressurized on the PET resin layer, thereby forming a plurality of pyramid shaped holes on the PET resin layer. A minimum distance (refer to the minimum distance W of FIG. 1A) between the two adjacent pyramid shaped holes was about 200 nm, a height of the pyramid shaped hole was 100 nm, and a ratio of width to height of a rectangle constituting a base side of the pyramid shaped hole was adjusted to be 2:1, wherein a width was about 100 nm. Then, the glass substrate was dipped in a mixture including F₂O₃ colloidal particles (hemitite) and water so that the F₂O₃ colloidal particles were provided in the pyramid shaped holes while having a FCC lattice structure in a self-assembly. FIG. 4A is an electron microscope photographic image of the F₂O₃ colloidal particles, wherein the average value of longer axis of the colloidal particles is about 200 nm. The glass substrate obtained as above was heat-treated at 80° C. for 10 minutes to form a visibility enhancing film, which includes a PET-based film and a plurality of photonic crystals formed inside a hole formed on the PET-based film, wherein each of the photonic crystals include Fe₂O₃ colloidal particles, and has a thickness of 160 μm. FIG. 5A is a photographic image of the F₂O₃ colloidal particles having a lattice structure in the photonic crystal of the visibility enhancing film.

### Example 2

A visibility enhancing film was prepared in the same manner as in Example 1, except that polystyrene (PS) colloidal particles having an average particle size of about 200 nm was used instead of the F₂O₃ colloidal particles. FIG. 4B is an electron microscope photographic image of the PS colloidal particles. As a result, a visibility enhancing film, which includes a PET-based film and a plurality of photonic crystals formed inside a hole formed on the PET-based film, wherein each of the photonic crystals include polystyrene (PS) colloidal particles, and has a thickness of 160 μm, was prepared. FIG. 5B is a photographic image of the polystyrene (PS) colloidal particles having a lattice structure in the photonic crystal of the visibility enhancing film.

The polystyrene (PS) colloidal particles were obtained by heating a mixture including deionized water, an emulsifier, sodium styrene sulfonate as a surfactant, and sodium hydrogen carbonate as a counteragent at 80° C. for 10 minutes, stirring the heated mixture, adding a styrene monomer to the resulting mixture, adding potassium persulfate as an initiator, and then performing a polymerization reaction under a nitrogen atmosphere.

### Comparative Example 1

A polarizing filter of Nitto (product name: HC Polarizing Film) was prepared.

### Evaluation Example

Table 1 below shows reflectivities, transmittances, and contrast ratios (CRs) of the visibility enhancing films of Examples 1 and 2, and the polarizing film of Comparative Example 1. In one embodiment, the surface A of the visibility enhancing film 10 of FIG. 1A may face toward an organic light emitting device (OLED), and internal light may be extracted from the OLED and projected to the surface A. Meanwhile, external light from external environment is incident on another surface of the visibility enhancing film 10 with the another surface being different from the surface A. In Table 1, the transmittance refers to the transmittance of the internal light extracted from the OLED at the surface A of the visibility enhancing film 10, and the reflectivity refers to the reflectivity of the external light at the another surface of the visibility enhancing film 10.

Table 1 shows average values of the reflectivities and the transmittances measured by irradiating a spectrum light of D65 International Standard Wavelength having a visible ray band from about 400 nm to about 700 m on the visible enhancing films of Examples 1 and 2 and the polarizing film of Comparative Example 1.

The contrast ratios (CRs) are measured by using an 8° cyan measuring method, and ACR1201, wherein a detector is SR3A, was used as a measuring device. While measuring the CRs, i) an integrating sphere was used, ii) a standard A-light source was used, iii) an aperture was 1°, and iv) luminance was from 0 to 10,000 lux.

TABLE 1

| Item | Comparative Example 1 | Example 1 | Example 2 |
|---|---|---|---|
| Reflectivity | 4.3% | 5.6% | 6.0% |
| Transmittance | 43% | 55.4% | 50.2% |
| CR(@10000Lux) | 2.5:1 | 3.7:1 | 3:1 |

Referring to Table 1, the visibility enhancing films of Examples 1 and 2 were found to have more excellent reflectivities, transmittances, and CRs compared to the polarizing film tested in Comparative Example 1.

The visibility enhancing film may effectively block an external light, and thus an organic light emitting apparatus using the visibility enhancing film may have excellent luminance and contrast ratio characteristics.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A visibility enhancing film, comprising:
a polymer film; and
photonic crystals disposed within a hole formed in the polymer film, with each of the photonic crystals comprised of colloidal particles.

2. The visibility enhancing film of claim 1, wherein the photonic crystals have a pyramid shape, a cone shape, or a rod shape.

3. The visibility enhancing film of claim 1, wherein the colloidal particles have a globular shape, an egg shape, or a peanut shape.

4. The visibility enhancing film of claim 1, wherein the colloidal particles are selected from the group consisting of a polymer, a metal hydroxide, a metal oxide, a quantum dot, and a combination of at least two thereof.

5. The visibility enhancing film of claim 4, wherein the colloidal particles are a polymer, wherein the polymer is selected from the group consisting of a polyester-based polymer, a polystyrene-based polymer, a polyacrylate-based polymer, a polymethacrylate-based polymer, a polycarbonate-based polymer, a polyether-based polymer, a polyalkyleneoxide-based polymer, a polyamide-based polymer, a polysiloxane-based polymer, and a combination of at least two thereof.

6. The visibility enhancing film of claim 4, wherein the colloidal particles are a metal hydroxide, wherein the metal hydroxide is selected from the group consisting of an iron hydroxide, an aluminum hydroxide, a zinc hydroxide, a titanium hydroxide, a cerium hydroxide, a tin hydroxide, a thallium hydroxide, a barium hydroxide, a yttrium hydroxide, a zirconium hydroxide, a copper hydroxide, and a combination of at least two thereof.

7. The visibility enhancing film of claim 4, wherein the colloidal particles are a metal oxide, wherein the metal oxide is selected from the group consisting of an iron oxide, an aluminum oxide, a zinc oxide, a titanium oxide, a cerium oxide, a tin oxide, a thallium oxide, a barium oxide, a yttrium oxide, a zirconium oxide, a copper oxide, and a combination of at least two thereof.

8. The visibility enhancing film of claim 4, wherein the colloidal particles are a quantum dot, wherein the quantum dot is selected from the group consisting of magnesium (Mg), cadmium (Cd), titanium (Ti), lithium (Li), copper (Cu), aluminum (Al), nickel (Ni), yttrium (Y), silver (Ag), manganese (Mn), vanadium (V), iron (Fe), lanthanum (La), tantalum (Ta), niobium (Nb), gallium (Ga), indium (In), sulfur (S), selenium (Se), phosphorus (P), arsenic (As), cobalt (Co), chromium (Cr), boron (B), nitrogen (N), antimony (Sb), and a combination of at least two thereof.

9. The visibility enhancing film of claim 1, wherein the colloidal particles are selected from the group consisting of starch, Arabic gum, clay, fat, and a combination of at least two thereof.

10. The visibility enhancing film of claim 1, wherein the colloidal particles included in the photonic crystal have a simple cubic lattice structure, a simple hexagonal lattice structure, a body centered cubic lattice structure, a face centered cubic lattice structure, a hexagonal close packed lattice structure, or a diamond lattice structure.

11. The visibility enhancing film of claim 1, wherein the polymer film is selected from the group consisting of a polyethyleneterephthalate-based resin, a polycarbonate-based resin, a polyethylenephthalate-based resin, a polyimide-based resin, a polyamide-based resin, a polyether-based resin, a polysulfone-based resin, a polypropylene-based resin, a polymethylmethacrylate-based resin, a acetylcellulose-based resin, a copolymer comprising at least two thereof, and a derivative thereof.

12. A method of forming a visibility enhancing film, the method comprising:
preparing a substrate;
forming, on the substrate, a polymer film forming material layer by providing a mixture comprising a polymer film forming material and a solvent;
forming, on the polymer film forming material layer, holes which receive a plurality of photonic crystals by contacting the polymer film forming material layer with a stamp having a predetermined pattern;
providing a mixture comprising a colloidal particle and a dispersion medium inside each of the holes;
removing the dispersion medium and the solvent by a thermal treatment.

13. The method of claim 12, wherein the holes have a pyramid shape, a cone shape, or a rod shape.

14. The method of claim 12, wherein the colloidal particle is selected from the group consisting of a polymer, a metal hydroxide, a metal oxide, a quantum dot, and a combination of at least two thereof.

15. The method of claim 12, wherein the colloidal particle is selected from the group consisting of starch, Arabic gum, clay, fat, and a combination of at least two thereof.

16. The method of claim 12, wherein the dispersion medium is selected from the group consisting of water, methanol, ethanol, ethyleneglycol, glycerol, perfluorodecalin, perfluoromethyldecalin, perfluorononane, perfluorocyclohexane, perfluoro-1,2-dimethylcyclohexane, perfluoro-2-methyl-2-pentene, perfluorokerosene, and a combination of at least two thereof.

17. An organic light-emitting apparatus, comprising:
an organic light emitting device; and
a visibility enhancing film formed in a path of light emitted from the organic light emitting device, with the visibility enhancing film comprising:
a polymer film; and
photonic crystals disposed within a hole formed in the polymer film, with each of the photonic crystals comprising colloidal particles.

18. The organic light-emitting apparatus of claim 17, wherein the visibility enhancing film is disposed to face toward the organic light emitting device.

19. The organic light-emitting apparatus of claim 17, further comprising an adhesive layer bonding the visibility enhancing film and the organic light emitting device.
